(19) United States
(12) Patent Application Publication
(10) Pub. No.: US 2026/0148922 A1
(43) Pub. Date: May 28, 2026

(54) ION BEAM SOURCE APPARATUS, ION BEAM PROCESSING SYSTEM, AND ION BEAM PROCESSING METHOD

(71) Applicant: SAMSUNG ELECTRONICS CO., LTD., Suwon-si (KR)

(72) Inventors: Seongjun HONG, Suwon-si (KR); Jongsoon PARK, Suwon-si (KR); Hyunho JUNG, Suwon-si (KR)

(73) Assignee: SAMSUNG ELECTRONICS CO., LTD., Suwon-si (KR)

(21) Appl. No.: 19/201,584

(22) Filed: May 7, 2025

(30) Foreign Application Priority Data
Nov. 27, 2024 (KR) 10-2024-0171849

(51) Int. Cl. H01J 37/09; H01J 37/08; H01J 37/244; H01L 21/263

(52) U.S. Cl. CPC H01J 37/09; H01J 37/08; H01J 37/244; H10P 50/20; H01J 2237/24564; H01J 2237/3174

(57) ABSTRACT

An ion beam source apparatus may include: a plasma chamber configured to generate plasma; and a slit structure configured to extract an ion beam from the plasma and radiate the ion beam toward a wafer, wherein the slit structure includes: a plasma plate on a side of the plasma chamber, the plasma plate including at least one opening through which the ion beam passes; at least one blocking bar within the plasma chamber, the at least one blocking bar spaced apart from the at least one opening by a gap, the gap being between the plasma plate and the at least one blocking bar in a first direction; and a lift structure connected to the at least one blocking bar, the lift structure configured to control an angle at which the ion beam passing through the at least one opening is radiated by adjusting the gap between the plasma plate and the at least one blocking bar in the first direction.

### CROSS-REFERENCE TO RELATED APPLICATION

This application claims priority to Korean Patent Application No. 10-2024-0171849, filed in the Korean Intellectual Property Office on Nov. 27, 2024, the disclosure of which is hereby incorporated by reference in its entirety.

### BACKGROUND

### 1. Field

Some embodiments of the present disclosure relate to an ion beam source apparatus, an ion beam processing system, and an ion beam processing method.

### 2. Description of Related Art

To manufacture a semiconductor device, a series of processes including etching, ashing, ion implantation, thin-film deposition, cleaning, etc., may be performed. In particular, the etching process may be a process of removing a specific area on a semiconductor substrate to form a desired pattern. The etching process can be carried out by an ion beam etching apparatus through which a plasma reaction is induced. The ion beam etching apparatus can convert a reactive gas into plasma and eliminate a material on the substrate surface using an ion beam within the generated plasma. As a result, a high-resolution pattern can be formed on the substrate, and the demand for miniaturization of semiconductor devices can be met.

An etching technology using ion beams makes the formation of fine patterns and a critical dimension transfer feasible in the semiconductor manufacturing process. To this end, various properties of an ion beam radiated from plasma onto a substrate surface may be appropriately controlled while processing the substrate using the ion beam.

### SUMMARY

According to some embodiments of the present disclosure, an ion beam source apparatus, an ion beam processing system, and an ion beam processing method may be provided that are capable of controlling an ion beam to be symmetrically incident on a wafer.

According to some embodiments of the present disclosure, an ion beam source apparatus, an ion beam processing system, and an ion beam processing method may be provided that are capable of controlling the incident angle of an ion beam without changing the energy of the ion beam.

According to some embodiments of the present disclosure, an ion beam source apparatus may be provided and include: a plasma chamber configured to generate plasma; and a slit structure configured to extract an ion beam from the plasma and radiate the ion beam toward a wafer, wherein the slit structure includes: a plasma plate on a side of the plasma chamber, the plasma plate including at least one opening through which the ion beam passes; at least one blocking bar within the plasma chamber, the at least one blocking bar spaced apart from the at least one opening by a gap, the gap being between the plasma plate and the at least one blocking bar in a first direction; and a lift structure connected to the at least one blocking bar, the lift structure configured to control an angle at which the ion beam passing through the at least one opening is radiated by adjusting the gap between the plasma plate and the at least one blocking bar in the first direction.

According to some embodiments of the present disclosure, an ion beam processing system may be provided and include: a plasma chamber configured to generate plasma; a process chamber connected to the plasma chamber, wherein the process chamber defines a space where processing of a wafer is performed using an ion beam extracted from the plasma; a slit structure between the plasma chamber and the process chamber, the slit structure configured to extract the ion beam from the plasma and radiate the ion beam toward the wafer; and a voltage system configured to be electrically connected to each of the plasma chamber, the slit structure, and the wafer to generate an electric field between the plasma chamber and the slit structure and between the slit structure and the wafer, wherein the slit structure includes: a plasma plate connected to the plasma chamber and including at least one opening through which the ion beam passes; at least one blocking bar within the plasma chamber, the at least one blocking bar spaced apart from the at least one opening by a gap, the gap being between the plasma plate and the at least one blocking bar in a first direction; and a lift structure connected to the at least one blocking bar, the lift structure configured to control an angle at which the ion beam passing through the at least one opening is radiated by adjusting the gap between the plasma plate and the at least one blocking bar in the first direction.

According to some embodiments of the present disclosure, an ion beam processing method may be provided and include: applying, by a voltage system of an ion beam processing system, a bias voltage to each of a plasma chamber of the ion beam processing system, a slit structure of the ion beam processing system, and a wafer, wherein the slit structure is between the plasma chamber and a process chamber of the ion beam processing system; generating, by the bias voltage, plasma using a process gas supplied into the plasma chamber; extracting, by the slit structure, an ion beam from the plasma and radiating the ion beam toward the wafer; and performing, in the process chamber, processing of the wafer using the ion beam, wherein the slit structure includes: a plasma plate on a side of the plasma chamber, the plasma plate including an opening through which the ion beam passes; a blocking bar within the plasma chamber, the blocking bar spaced apart from the opening by a gap, the gap being between the plasma plate and the blocking bar in a first direction; and a lift structure connected to the blocking bar, the lift structure configured to control an angle at which the ion beam passing through the opening is radiated by adjusting the gap between the plasma plate and the blocking bar in the first direction.

According to some embodiments of the present disclosure, the distance between the wafer and the plasma plate of the slit structure configured to extract an ion beam from plasma and radiate the ion beam toward the wafer may be constant, so that it may be possible for the ion beam processing system to maintain the energy of an ion beam passing through the first opening and reaching the wafer.

According to some embodiments of the present disclosure, the distance between the plasma plate and the blocking bar of the slit structure may be precisely adjusted, so that it may be possible for the ion beam processing system to allow ion beams passing through each of the two openings on each side of the blocking bar to be radiated onto the wafer symmetrically.

According to some embodiments of the present disclosure, the distance between the plasma plate and the blocking bar of the slit structure may be precisely adjusted, so that it may be possible for the ion beam processing system to effectively adjust the incident angle of an ion beam on the wafer without changing other process conditions.

### BRIEF DESCRIPTION OF DRAWINGS

Non-limiting example embodiments of the present disclosure will be described with reference to the accompanying drawings. In this regard, similar reference numerals refer to similar components, but embodiments of the present disclosure are not limited thereto.

FIG. 1 is a cross-sectional view of an ion beam processing system according to an embodiment of the present disclosure.

FIG. 2 is a view for illustrating an ion beam processing system according to an embodiment of the present disclosure.

FIG. 3 is a view for illustrating an ion beam processing system according to an embodiment of the present disclosure.

FIG. 4 is a perspective view for illustrating a slit structure according to an embodiment of the present disclosure.

FIG. 5A is a top view for illustrating the slit structure in FIG. 4.

FIG. 5B is a side view for illustrating the slit structure in FIG. 4.

FIG. 5C is a cross-sectional view for illustrating the slit structure in FIG. 4.

FIG. 6 is a perspective view for illustrating a slit structure according to an embodiment of the present disclosure.

FIG. 7A is a top view for illustrating the slit structure in FIG. 6.

FIG. 7B is a side view for illustrating the slit structure in FIG. 6.

FIG. 7C is a cross-sectional view for illustrating the slit structure in FIG. 6.

FIG. 8 is a perspective view for illustrating a slit structure according to an embodiment of the present disclosure.

FIG. 9A is a top view for illustrating the slit structure in FIG. 8.

FIG. 9B is a side view for illustrating the slit structure in FIG. 8.

FIG. 9C is a cross-sectional view for illustrating the slit structure in FIG. 8.

FIG. 9D is a cross-sectional view for illustrating the slit structure in FIG. 8.

FIG. 10 is an exploded perspective view for illustrating a slit structure according to an embodiment of the present disclosure.

FIG. 11 is a side view for illustrating the slit structure in FIG. 10.

FIG. 12 is a cross-sectional view for illustrating the slit structure in FIG. 10.

FIG. 13 is a cross-sectional view for illustrating an ion beam processing system according to an embodiment of the present disclosure.

FIG. 14 is a cross-sectional view for illustrating an ion beam processing system according to an embodiment of the present disclosure.

FIG. 15A is a top view for illustrating the slit structure in FIG. 14.

FIG. 15B is a side view for illustrating the slit structure in FIG. 14.

FIG. 15C is a cross-sectional view for illustrating the slit structure in FIG. 14.

FIG. 16 is a flowchart for illustrating an ion beam processing method according to an embodiment of the present disclosure.

### DETAILED DESCRIPTION

A wafer processing apparatus according to some non-limiting example embodiments of the present disclosure will be described in detail with reference to the accompanying drawings. However, in the following description, specific descriptions of widely known functions or components may be omitted when there is a risk of unnecessarily obscuring the gist of the present disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

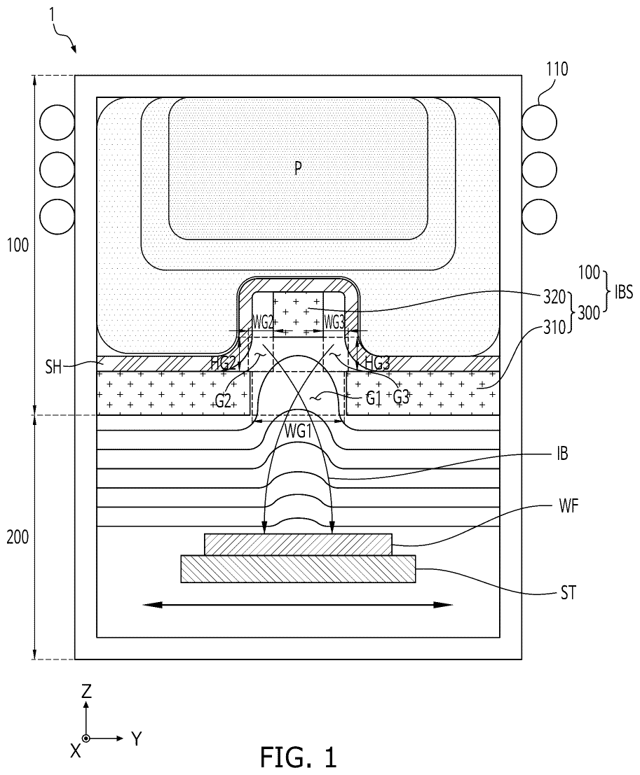

FIG. 1 is a cross-sectional view of an ion beam processing system according to an embodiment of the present disclosure.

An ion beam processing system 1 according to an embodiment of the present disclosure may be an apparatus that processes a wafer WF using an ion beam IB. For example, the ion beam processing system 1 may perform an etching process (e.g., an ion beam etching process) on the wafer WF using the ion beam IB. However, embodiments of the present disclosure are not limited thereto, and the ion beam processing system 1 may include an ion beam processing apparatus that carries out various processes for manufacturing semiconductor by using a slit structure 300 that extracts the ion beam IB from plasma P. For instance, the ion beam processing system 1 may be an apparatus that performs an ion implantation process on a wafer using an ion beam. The wafer WF may be a silicon (Si) wafer, but embodiments of the present disclosure are not limited thereto.

Referring to FIG. 1, the ion beam processing system 1 may include a plasma chamber 100, a process chamber 200, the slit structure 300, a gas supply apparatus, a plasma generation apparatus 110, etc. Among the components of the ion beam processing system 1, the plasma chamber 100 and the slit structure 300 may form an ion beam source apparatus IBS.

In an embodiment, the ion beam source apparatus IBS may be configured to generate the ion beam IB. The ion beam source apparatus IBS may extract ions from the plasma P to generate the ion beam IB. An ion beam IB emitted from the ion beam source apparatus IBS may be sent to the process chamber 200. A wafer WF may be processed by the ion beam IB in the process chamber 200.

In an embodiment, the plasma chamber 100 may be configured to provide a space for generating plasma. The space for generating plasma may be connected to a gas supply apparatus. Some of the gas supplied from the gas supply apparatus may be converted into the plasma P in the space for generating plasma.

In an embodiment, the plasma generation apparatus 110 may be configured to generate the plasma P in the space for generating plasma. The plasma generation apparatus 110 may be coupled with the plasma chamber 100. Referring to FIG. 1, the plasma generation apparatus 110 may include a radio frequency (RF) coil. The RF coil may be configured to surround the outer surface of the plasma chamber 100. An electric field and/or a magnetic field may be formed in the space for generating plasma within the plasma chamber 100 by the RF coil. As a result, some of the gas within the space for generating plasma may be converted into the plasma P. However, the configuration of the plasma generation apparatus 110 is not limited thereto. For example, the plasma generation apparatus 110 may generate the plasma P using electromagnetic waves generated by a microwave radiation device. For another example, the plasma generation apparatus 110 may generate the plasma P through a potential difference between electrodes formed by a direct current (DC) discharge device.

In an embodiment, the slit structure 300 may be connected to the plasma chamber 100. The slit structure 300 may be positioned between the plasma chamber 100 and the process chamber 200. The slit structure 300 may be configured to extract an ion beam from the plasma P within the space for generating plasma. In addition, the slit structure 300 may be configured to radiate the extracted ion beam IB toward the wafer WF within the process chamber 200. Referring to FIG. 1, the slit structure 300 may include a plasma plate 310, a blocking bar 320, and a lift structure.

In an embodiment, the plasma plate 310 may be connected to one side (e.g., a lower side) of the plasma chamber 100. The plasma plate 310 may include an opening (e.g., a hole such as, for example, a slit). The plasma plate 310 may provide a first opening G1 of the plasma chamber 100. Here, the first opening G1 may have the shape of a slit penetrating the plasma plate 310 and extending in one direction (e.g., an X direction). In addition, the first opening G1 may have a width WG1 in the longitudinal direction of the slit (e.g., the X direction) that is constant. The ion beam IB may pass through the first opening G1 formed in the plasma plate 310 and be emitted to the outside of the plasma chamber 100. The ion beam IB that has passed through the first opening G1 formed in the plasma plate 310 may be radiated onto the wafer WF within the process chamber 200.

In an embodiment, the plasma plate 310 may be connected to a voltage system (e.g., a power supply). By the voltage system, a first voltage, which has been predetermined, may be applied to the plasma plate 310. The plasma plate 310 may be formed of a conductive material to which the first voltage can be applied. However, the material and/or structure of the plasma plate 310 is not limited thereto. For example, the plasma plate 310 may have a multilayer structure with a first layer formed of an insulating material and a second layer formed of a conductive material. Here, the first layer of the multilayer structure of the plasma plate 310 may be arranged to face (e.g., upwards) the internal space of the plasma chamber 100, and the second layer may be disposed to face (e.g., downwards) a space external of the plasma chamber 100.

In an embodiment, the blocking bar 320 may be placed within the plasma chamber 100. The blocking bar 320 may be spaced apart from the plasma plate 310 by a predetermined distance in a first direction (e.g., a Z direction). The blocking bar 320 may guide the ion beam IB extracted from the plasma P to be radiated onto the wafer WF at a specific incidence angle. The ion beam IB may pass through a second opening G2 and a third opening G3 formed between the blocking bar 320 and the plasma plate 310 at a specific angle. Here, the second opening G2 may have a height HG2 in the first direction (e.g., the Z direction) and a width WG2 in a third direction (e.g., a Y direction). In addition, the third opening G3 may have a height HG3 in the first direction Z and a width WG3 in the third direction (e.g., the Y direction). As the height and/or width of the opening formed between the blocking bar 320 and the plasma plate 310 is adjusted, the direction or angle at which the ion beam IB is radiated onto the wafer WF may be controlled.

In an embodiment, the blocking bar 320 may be connected to a voltage system. A predetermined second voltage may be applied to the blocking bar 320 by the voltage system. The blocking bar 320 may be formed of a conductive material to which the second voltage can be applied. However, the material and/or structure of the blocking bar 320 is not limited thereto. For example, the blocking bar 320 may have a multilayer structure. A first layer of the multilayer structure of the blocking bar 320 may be formed of an insulating material, and a second layer of the multilayer structure may be formed of a conductive material. Here, in the multilayer structure of the blocking bar 320, the first layer may be arranged to face (e.g., upwards) the internal space of the plasma chamber 100, and the second layer may be disposed to face (e.g., downwards) the space external of the plasma chamber 100.

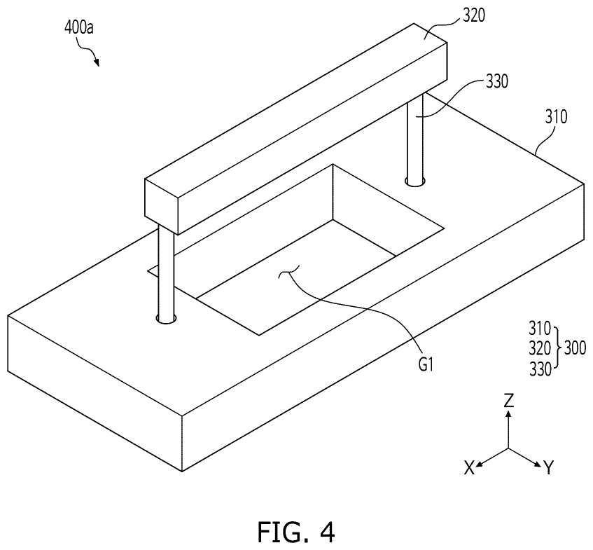

In an embodiment, the lift structure may be connected to the blocking bar 320. The lift structure may be configured to adjust the relative position of the blocking bar 320 with respect to the plasma plate 310. The lift structure may adjust the gap between the blocking bar 320 and the plasma plate 310 by moving or raising the blocking bar 320 in one direction (e.g., the Z direction). As a result, the height of the opening formed between the plasma plate 310 and the blocking member 320 may be adjusted, and the angle at which an ion beam is radiated onto the wafer WF may be controlled. The lift structure may be integrally connected to one surface of the blocking bar 320. For example, the lift structure may be integrally connected to the lower surface of the blocking bar 320 (e.g., the surface of the blocking bar 320 facing the wafer WF). Details of the structure and function of the slit structure 300 including the lift structure will be described below with reference to at least FIG. 4.

In an embodiment, the gas supply device may be connected to the plasma chamber 100. The gas supply device may be configured to supply a process gas into the space for generating plasma by being connected to the plasma chamber 100. For example, the gas supply device may include a gas tank, a compressor, a valve, etc.

In an embodiment, the process chamber 200 may be configured to provide a process space. A process for the wafer WF may be performed using an ion beam in the process space of the process chamber 200. The process chamber 200 may be connected to the ion beam source apparatus IBS. The ion beam source apparatus IBS may be coupled to one side (e.g., an upper side) of the process chamber 200. Through the slit structure 300, the space for generating plasma in the plasma chamber 100 may be connected to the process space in the process chamber 200. However, the structure of the process chamber 200 is not limited thereto. For example, the process chamber 200 may be arranged to surround the ion beam source apparatus IBS.

In an embodiment, a support (e.g., a stage ST) may be arranged in the process space of the process chamber 200. The wafer WF may be placed on the stage ST. The stage ST may be positioned inside the process space so that the wafer WF is spaced apart from the ion beam source apparatus IBS by a certain distance. For example, the stage ST may be an electrostatic chuck (ESC) for holding the wafer WF located thereon by electrostatic attraction. The electrostatic chuck may fix the wafer WF. The electrostatic chuck may hold the wafer WF with an electrostatic force by a DC voltage supplied by a DC power source. However, the structure of the stage ST where the wafer WF is disposed is not limiter thereto, and the stage ST may have diverse structures where the wafer WF is arranged and fixed and the process on the wafer WF can be performed. The stage ST on which the wafer WF is placed may be raised and/or rotated so that an ion beam generated from the ion beam source apparatus IBS is incident on the wafer WF at a specific angle.

In an embodiment, a vacuum pump may be connected to the process space in the process chamber 200. By the vacuum pump, the process space may be substantially a vacuum during the process on the wafer WF.

In an embodiment, the voltage system may be configured to apply a bias voltage to each of the plasma chamber 100, the slit structure 300, and/or the wafer WF to control the plasma state and/or the energy and incident angle of the ion beam IB. The voltage system may separately apply a bias voltage to the plasma plate 310 and the blocking bar 320. As a result, it may be possible for the voltage system to adjust an electric field within a plasma sheath region SH and optimize path of an ion beam. In addition, the voltage system may adjust collision energy of an ion beam on the surface of the wafer WF by controlling the bias voltage applied to the wafer WF.

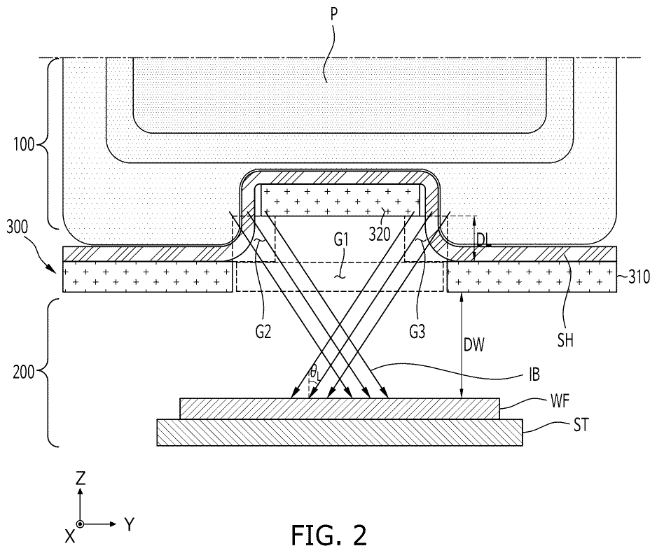

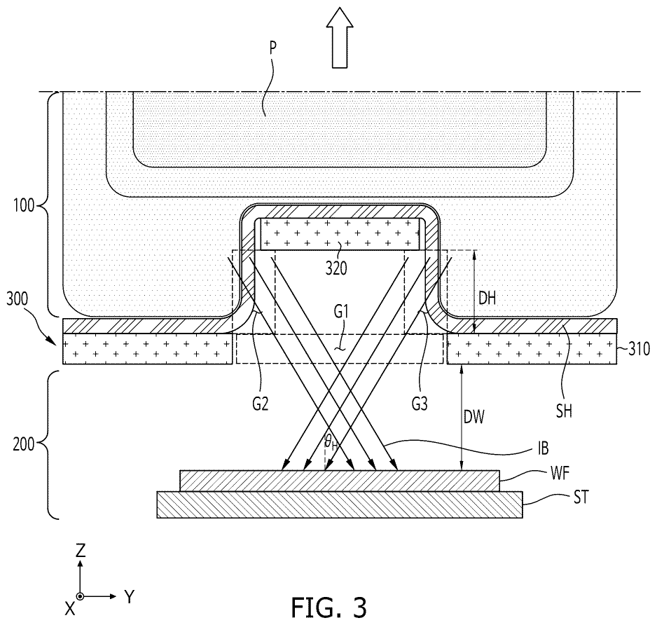

FIGS. 2 and 3 are views for illustrating an ion beam processing system according to an embodiment of the present disclosure.

Referring to FIGS. 2 and 3, the ion beam processing apparatus may include the plasma chamber 100, the process chamber 200, and the slit structure 300 disposed between the plasma chamber 100 and the process chamber 200. The slit structure 300 may include the plasma plate 310 placed on one side (e.g., a lower side) of the plasma chamber 100 and the blocking bar 320 disposed within the plasma chamber 100 and spaced apart from the opening formed in the plasma plate 310. In the process chamber 200, a process of processing the wafer WF using the ion beam IB may be performed, and the stage ST and the wafer WF placed on the stage ST may be arranged. Hereinafter, parts of the descriptions of FIGS. 2 and 3 overlapping with the description of FIG. 1 may be summarized or not repeated.

In an embodiment, the plasma P and the plasma sheath region SH may be formed inside the plasma chamber 100. The plasma P may be a mixture of ions and electrons. The plasma P may be maintained at a predetermined density inside the plasma chamber 100. The plasma sheath region SH may be formed along the boundary between the plasma P and the slit structure 300. In addition, the plasma sheath region SH may be formed in the space between the plasma P and the inner wall of the plasma chamber 100. The plasma sheath region SH may be formed based on a first electric field generated by a voltage applied to the plasma chamber 100 and/or a voltage applied to the slit structure 300. The plasma sheath region SH may allow the ion beam IB to be emitted in a specific direction inside the process chamber 200 through the slit structure 300.

In an embodiment, the slit structure 300 may be configured to extract the ion beam IB from the plasma P. The plasma plate 310 of the slit structure 300 may include the first opening G1 through which the ion beam IB is emitted into a space external of the plasma chamber 100 (e.g., the process space of the process chamber 200). The ion beam IB may pass through the first opening G1 and be radiated onto the wafer WF within the process chamber 200. The blocking bar 320 of the slit structure 300 may be spaced apart from the plasma plate 310 by a predetermined distance. For example, referring to FIG. 2, the blocking bar 320 may be spaced apart from one side of the first opening G1 of the plasma plate 310 or one side of the plasma plate 310 by a first distance DL predetermined in the first direction (e.g., the Z direction), and may be arranged parallel to the first opening G1. For another example, referring to FIG. 3, the blocking bar 320 may be spaced apart from one side of the first opening G1 of the plasma plate 310 by a second distance DH, which has been predetermined, and may be arranged parallel to the first opening G1. The blocking bar 320 may form the second opening G2 and the third opening G3 between itself and the plasma plate 310. The second opening G2 and the third opening G3 may be formed in the first direction (e.g., the Z direction), from the first opening G1 and the second direction (e.g., the Y direction), of the blocking bar 320. Here, the second direction (e.g., the Y direction), may be a direction intersecting the first direction (e.g., the X direction). The ion beam IB may pass through the first opening G1 through the second opening G2 and the third opening G3 and then be radiated onto the wafer WF.

In an embodiment, the process chamber 200 may be configured to provide a movement path for the ion beam IB. The ion beam IB may be extracted from the plasma P by the slit structure 300. The ion beam IB, which has been extracted, may be radiated onto the wafer WF with a specific energy and incident angle along the movement path generated within the process chamber 200. The energy of the ion beam IB may be affected by various factors including the strength of an electric field formed within the process chamber 200 and the potential difference between the slit structure 300 and the wafer WF. Factors including the values of bias voltage applied to each of the plasma plate 310 of the slit structure 300 and the wafer WF, a distance DW between the plasma plate 310 and the wafer WF, etc., may affect the strength of the electric field. The incident angle of the ion beam IB may be affected by the shape of the equipotential surface of the electric field formed within the process chamber 200. In addition, the arrangement of the slit structure 300 and the wafer WF may affect the shape of the equipotential surface of the electric field. Here, the arrangement of the slit structure 300 and the wafer WF may include the first opening G1 of the plasma plate 310, the second opening G2 and the third opening G3 between the plasma plate 310 and the blocking bar 320, the first distance DL and the second distance DH (e.g., separation distances), and/or the distance DW between the plasma plate 310 and the wafer WF, etc.

In an embodiment, a second electric field, which has been predetermined, may be formed between the slit structure 300 and the wafer WF. A first voltage, which has been predetermined, may be applied to the slit structure 300. A voltage system may apply the first voltage (e.g., 0 V and a ground voltage) to each of the plasma plate 310 and the blocking bar 320. A second voltage, which has been predetermined, may be applied to the wafer WF. The voltage system may apply the second voltage (e.g., a negative voltage) to the wafer WF and/or the stage ST. A potential difference between the first voltage applied to the slit structure 300 and the second voltage applied to the wafer WF may form a second electric field between the slit structure 300 and the wafer WF. Although FIGS. 2 and 3 illustrate the ion beam IB passing through the first opening G1, the second opening G2, and the third opening G3 in a straight line, the ion beam IB may actually pass through the first opening G1, the second opening G2, and the third opening G3 in a direction perpendicular to the equipotential surface of the second electric field and then be radiated onto the wafer WF.

As the distance DW between the plasma plate 310 and the wafer WF increases, the incident angle of the ion beam IB to the wafer WF may decrease. In addition, assuming that the values of bias voltage applied to each of the plasma plate 310 and the wafer WF are equal, as the distance DW between the plasma plate 310 and the wafer WF increases, the energy of the ion beam IB with respect to the wafer WF may decrease.

Referring to FIGS. 2 and 3, assuming that the distance DW between the plasma plate 310 and the wafer WF is constant, as the distance (e.g., the first distance DL and the second distance DH) between the plasma plate 310 and the blocking bar 320 increases (e.g., the first distance DL is less than the second distance DH), the incident angle θ_{L} and θ_{H} of the ion beam IB to the wafer WF may increase (e.g., the incident angle is θ_{L} is less than the incident angle θ_{H}).

In an embodiment, in the case of the ion beam processing system as described above, the distance DW between the plasma plate 310 and the wafer WF may be constant, thereby maintaining the energy of the ion beam IB reaching the wafer WF.

In an embodiment, the distance (e.g., the first distance DL and the second distance DH) between the plasma plate 310 and the blocking bar 320 of the ion beam processing system may be precisely adjusted, so that the ion beams IB passing through the second opening G2 and the third opening G3 on each side of the blocking bar 320 may be radiated symmetrically onto the wafer WF. In addition, the distance (e.g., the first distance DL and the second distance DH between the plasma plate 310 and the blocking bar 320 of the ion beam processing system may be precisely adjusted, so that it may be possible to adjust the incident angle of the ion beam IB on the wafer without changing other process conditions.

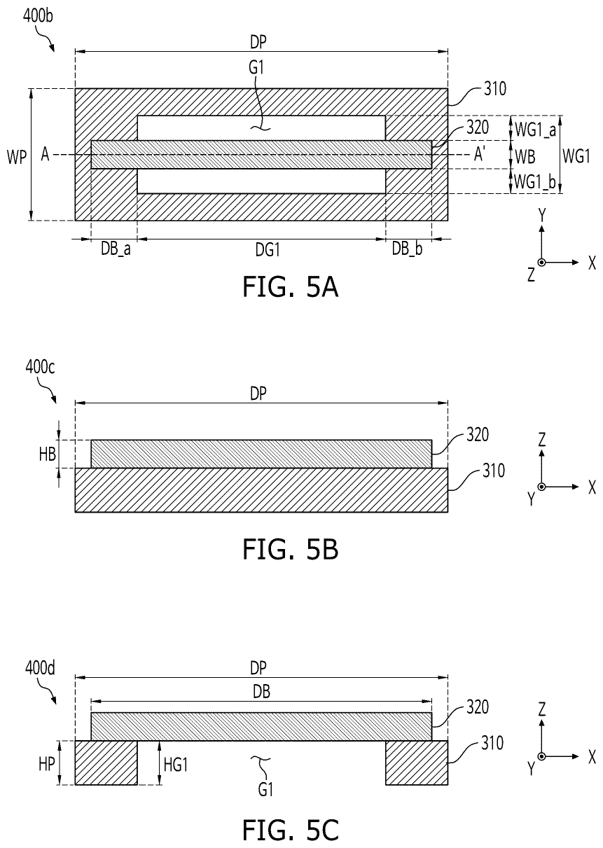

FIG. 4 is a perspective view for illustrating a slit structure according to an embodiment of the present disclosure. FIGS. 5A-C are a top view, side view, and cross-sectional view for illustrating the slit structure in FIG. 4, respectively. Hereinafter, parts of the descriptions of FIGS. 4 and 5A-C overlapping with the descriptions of FIGS. 1 to 3 may be summarized or not repeated.

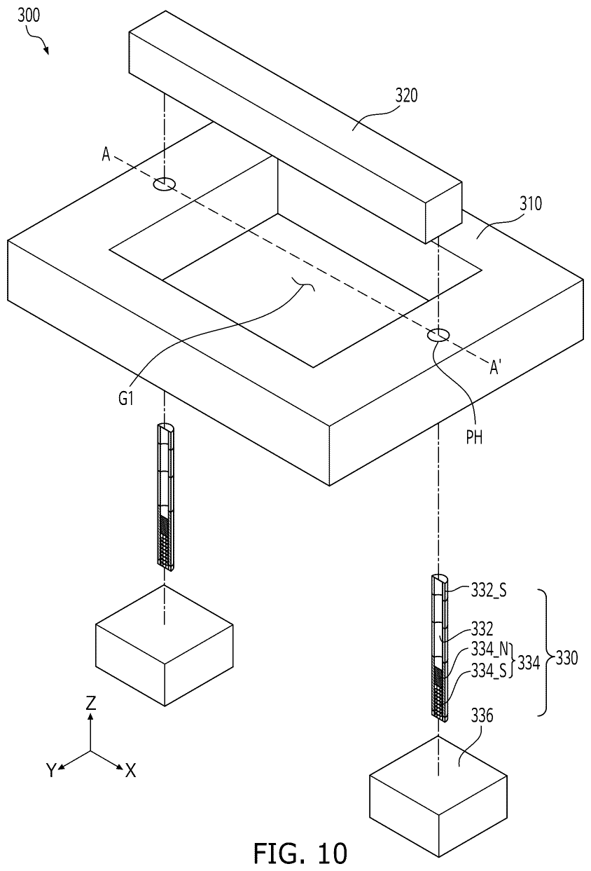

Referring to the perspective view 400a of FIG. 4, the slit structure 300 may include the plasma plate 310, the blocking bar 320, and a lift structure 330. The plasma plate 310 may be arranged on one side of a plasma chamber and may include the first opening G1. The blocking bar 320 may be placed within the plasma chamber so that there is a gap between the blocking bar 320 and the first opening G1. The lift structure 330 may be connected to the blocking bar 320. The gap between the plasma plate 310 and the blocking bar 320 may be adjusted in a first direction (e.g., the Z direction), by the lift structure 330. A detailed description of the lift structure will be provided below with reference to FIGS. 10 to 12.

Referring to the top view 400b, the side view 400c, and the A-A′ cross-sectional view 400d of FIGS. 5A-C, in an embodiment, the plasma plate 310 may have a height HP in a first direction (e.g., the Z direction), a length DP in a second direction (e.g., the X direction), intersecting the first direction (e.g., the Z direction), and a width WP in a third direction (e.g., the Y direction), intersecting the first direction (e.g., the Z direction) and the second direction (e.g., the X direction). Here, the length DP and the width WP of the plasma plate 310 may correspond to the length and the width of a plasma chamber connected to the plasma plate 310. As a result, the plasma plate 310 may be connected to one side surface of the plasma chamber (e.g., a side surface connected to a process chamber), provide an opening formed on the side surface, and define a space for generating plasma of the plasma chamber and a process space of the process chamber.

In an embodiment, the plasma plate 310 may include the first opening G1 through which an ion beam passes. The first opening G1 may have the shape of a slit extending in a second direction (e.g., the X direction). The first opening G1 may have a height HG1 in a first direction (e.g., the Z direction), a length DG1 in the second direction (e.g., the X direction) intersecting the first direction (e.g., the Z direction), and a width WG1 in a third direction (e.g., the Y direction) intersecting the first direction (e.g., the Z direction) and the second direction (e.g., the X direction). Here, the height HG1 of the first opening G1 may correspond to (e.g., be the same as) the height HP of the plasma plate 310. The length DG1 and the width WG1 of the first opening G1 may be smaller than the length DP and the width WP of the plasma plate 310, respectively.

In an embodiment, the blocking bar 320 may be positioned to overlap with at least a portion of the plasma plate 310 in a first direction (e.g., the Z direction). The blocking bar 320 may be arranged to face the first opening G1. The blocking bar 320 may have a height HB in the first direction (e.g., the Z direction), a length DB in a second direction (e.g., the X direction) intersecting the first direction (e.g., the Z direction), and a width WB in a third direction (e.g., the Y direction) intersecting the first direction (e.g., the Z direction) and the second direction (e.g., the X direction). The width WB of the blocking bar 320 may be smaller than the width WG1 of the first opening G1.

Referring to the top view 400b of FIG. 5A, the blocking bar 320 may be positioned to cover at least a portion of the first opening G1. Portions of the first opening G1 that are not covered by the blocking bar 320 may have widths WG1_a and WG1_b, respectively. These widths WG1_a and WG1_b may correspond to each of the widths WG2 and WG3 of the second opening G2 and the third opening G3 in FIG. 1. Here, the widths WG1_a and WG1_b may be equal to each other. As a result, ion beams passing through the first opening G1 through the second opening G2 and the third opening G3, respectively, may have the same properties (e.g., an incident angle to a wafer, energy, etc.).

In an embodiment, the blocking bar 320 may be positioned to cover at least a portion of the first opening G1. Therefore, it may be possible for the blocking bar 320 to control the straightness of an ion beam passing through the first opening G1 of the plasma plate 310 to allow the ion beam to be radiated onto the wafer at a specific angle. The blocking bar 320 may provide the second opening G2 and the third opening G3 between itself and the plasma plate 310. An ion beam may obtain specific angular properties as it passes through the second opening and the third opening. The ion beam that has obtained specific angular properties while passing through the first opening G1 may be radiated onto the wafer at a specific incident angle.

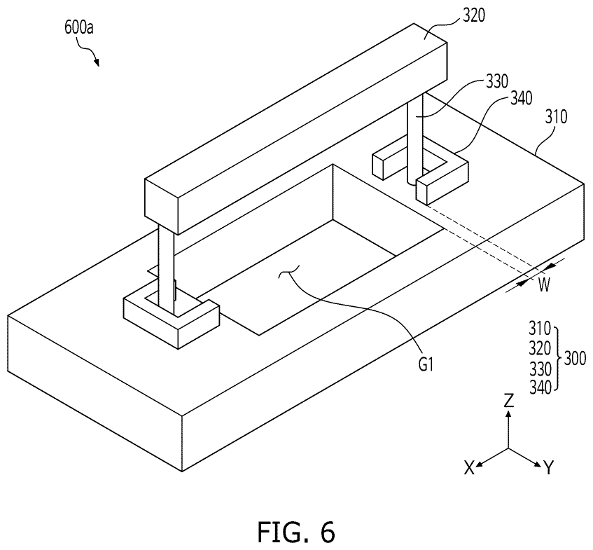

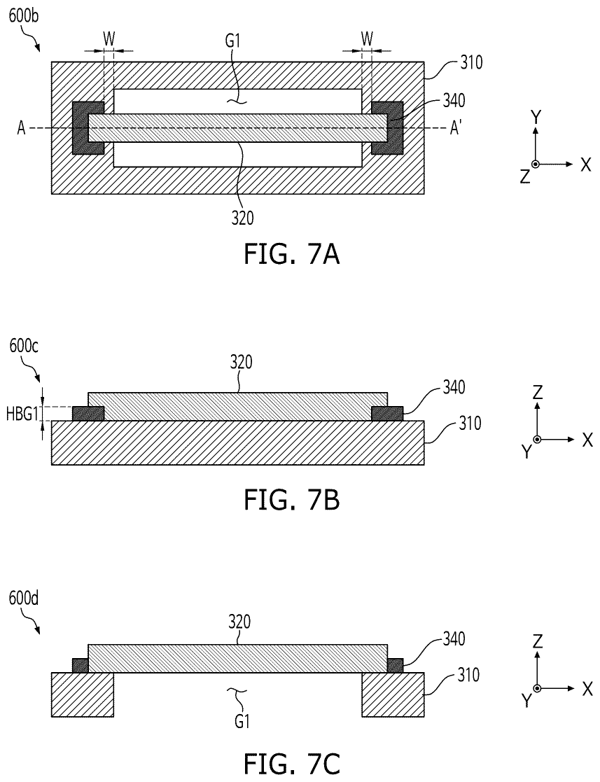

FIG. 6 is a perspective view 600a for illustrating a slit structure according to an embodiment of the present disclosure. FIGS. 7A-C are a top view 600b, side view 600c, and cross-sectional view 600d for illustrating the slit structure in FIG. 6, respectively.

Referring to the perspective view 600a of FIG. 6, the slit structure 300 may include the plasma plate 310, the blocking bar 320, the lift structure 330, and a blocking bar guide 340. The blocking bar guide 340 may be configured to allow the blocking bar 320 to be aligned to be horizontal to the plasma plate 310. Hereinafter, parts of the descriptions of FIGS. 6 and 7 overlapping with the descriptions of FIGS. 1 to 5 may be summarized or not repeated.

In an embodiment, the blocking bar guide 340 may be placed on one side of the plasma plate 310. The blocking bar guide 340 may be mounted on the plasma plate 310 so that the blocking bar 320 may symmetrically cover the first opening G1. The blocking bar guide 340 may be configured to allow the blocking bar 320 to be arranged symmetrically based on the center line A-A′ in a second direction (e.g., the X direction) of the first opening G1.

In an embodiment, the blocking bar guide 340 may be configured to have minimal thermal or physical influence on a plasma environment. For example, referring to FIG. 6, the blocking bar guide 340 may be spaced apart from the first opening G1 by a predetermined distance W on one surface (e.g., an upper surface) of the plasma plate 310. Accordingly, it may be possible for the blocking bar guide 340 to stably support and align the blocking bar 320 without affecting the path and direction of an ion beam passing through the first opening G1. In addition, an electric field distribution within a plasma sheath region may be constant, thereby improving the symmetry and uniformity of an ion beam passing through the first opening G1 and radiated onto a wafer.

Referring to FIGS. 6 and 7A-C, the blocking bar guide 340 may be configured to surround both ends of the blocking bar 320. For example, the blocking bar guide 340 may have a rectangular C-shape. However, the shape of the blocking bar guide 340 is not limited thereto, and the blocking bar guide 340 may be formed in various shapes to support the blocking bar 320 to enable the blocking bar 320 to evenly cover the first opening G1. For example, the blocking bar guide 340 may be formed in a curved C-shape or an open frame structure.

In an embodiment, when designing the blocking bar guide 340, the blocking bar guide 340 may be sought to minimize the chemical reactivity of the blocking bar guide 340 with plasma and the influence of the blocking bar guide 340 on energy and direction of an ion beam. For example, a height HBG1 of the blocking bar guide 340 in a first direction (e.g., the Z direction) may be lower than the height of the blocking bar 320.

In an embodiment, the blocking bar guide 340 may be formed of a ceramic material or an insulating material having excellent durability and thermal stability. For example, the blocking bar guide 340 may be formed of a ceramic material. For another example, the surface of the blocking bar guide 340 may be dielectrically coated to prevent charge accumulation due to interaction with an ion beam. According to another example, the blocking bar guide 340 may be formed of a carbon-based composite material or a high-temperature refractory ceramic such as silicon carbide. The blocking bar guide 340 formed of such materials may maintain stability even in a plasma environment and allow path and direction of an ion beam to be maintained.

Through the blocking bar guide 340 including such features, the ion beam processing system may determine the position of a starting point of the blocking bar 320 to enable the blocking bar 320 to evenly cover the first opening G1, thereby maintaining the symmetry of ion beams radiated onto a wafer and the accuracy of the incident angle thereof. In addition, because the features can be obtained by attaching a structure separate from the plasma plate 310, it may be possible to easily change the design depending on various process conditions.

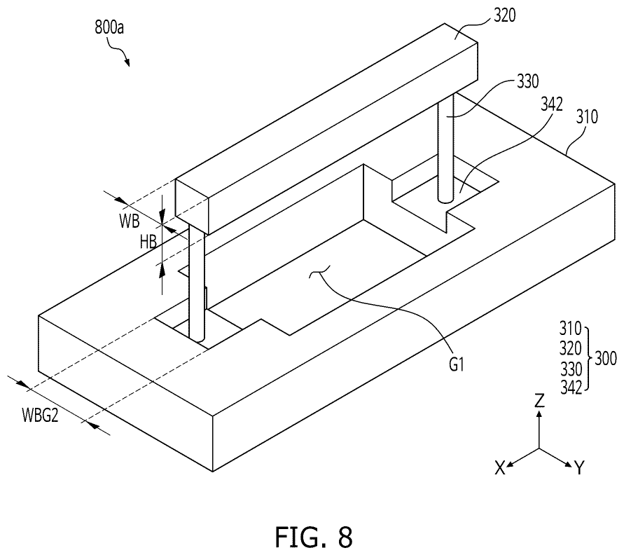

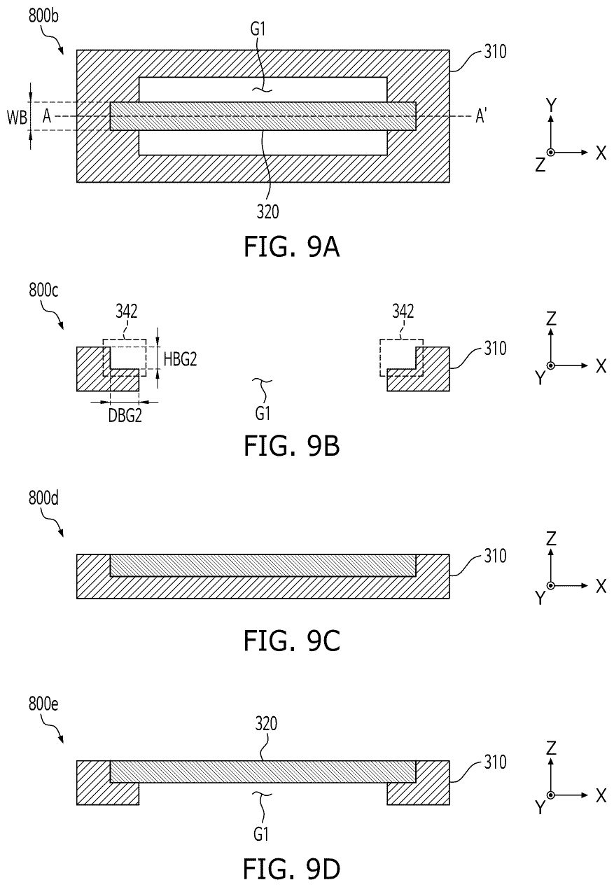

FIG. 8 is a perspective view 800a for illustrating a slit structure according to an embodiment of the present disclosure. FIGS. 9A-D is a top view 800b, side view 800c, and cross-sectional views 800d and 800e for illustrating the slit structure in FIG. 8, respectively.

Referring to the perspective view 800a of FIG. 8, the slit structure 300 may include the plasma plate 310, the blocking bar 320, the lift structure 330, and a blocking bar guide 342. The blocking bar guide 342 may be configured to allow the blocking bar 320 to be aligned to be horizontal to the plasma plate 310. Hereinafter, parts of the descriptions of FIGS. 8 and 9 overlapping with the descriptions of FIGS. 1 to 7 may be summarized or not repeated.

In an embodiment, the blocking bar guide 342 may be placed on or in one surface (e.g., an upper surface) of the plasma plate 310. The blocking bar guide 342 may have a concave shape sunken to correspond to the shape of both ends of the blocking bar 320 on or in one surface of the plasma plate 310. For example, the blocking bar guide 342 may have a concave shape in one surface of the plasma plate 310 to stably fix both ends of the blocking bar 320. Referring to the cross-sectional views 800d and 800e of FIG. 9C-D, the blocking bar guide 342 may be formed by engraving a portion of the plasma plate 310.

In an embodiment, the blocking bar guide 342 may be configured to allow the blocking bar 320 to be stably supported. For example, an engraved depth HBG2 of the blocking bar guide 342 in a first direction (e.g., the Z direction) may correspond to (e.g., be the same as) the height HB of the blocking bar 320. The sum of two times an engraved length DBG2 of the blocking bar guide 342 in a second direction (e.g., the X direction), and the length of the first opening G1, may correspond to (e.g., be the same as) the length of the blocking bar 320. An engraved width WBH2 of the blocking bar guide 342 in a third direction (e.g., the Y direction) may correspond to the width WB of the blocking bar 320.

The blocking bar guide 342 formed by engraving the plasma plate 310 may be formed as an integral part of the plasma plate 310, thereby improving the structural integrity of the slit structure. In addition, durability in response to vibration or thermal expansion that may occur during processing of a wafer may be guaranteed.

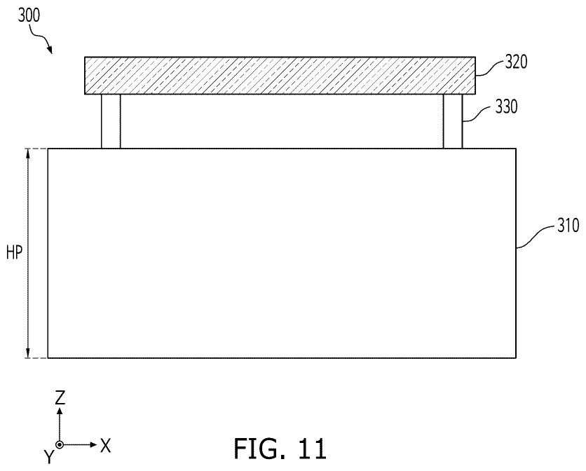

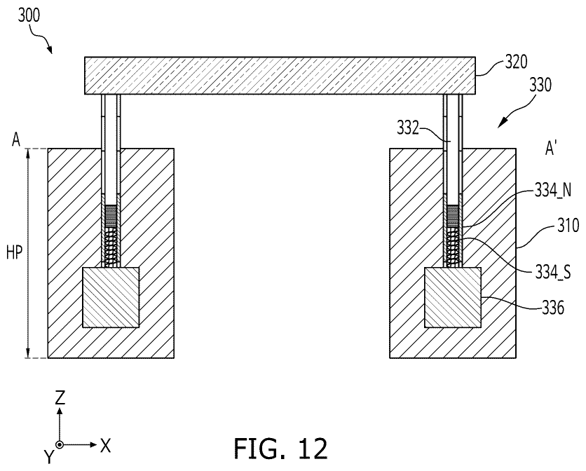

FIG. 10 is an exploded perspective view for illustrating a slit structure according to an embodiment of the present disclosure. FIG. 11 is a side view for illustrating the slit structure in FIG. 10. FIG. 12 is a cross-sectional view for illustrating the slit structure in FIG. 10.

Referring to FIG. 10, the slit structure 300 may include the plasma plate 310, the blocking bar 320, and the lift structure 330. Hereinafter, parts of the descriptions of FIGS. 10 and 11 overlapping with the descriptions of FIGS. 1 to 9 may be summarized or not repeated.

The lift structure 330 may be configured to control the angle at which an ion beam passing through the first opening G1 is radiated onto a wafer by adjusting the gap between the plasma plate 310 and the blocking bar 320. The lift structure 330 may include a support 332, an actuator 334, and a driving source 336.

In an embodiment, the lift structure 330 may include the support 332. The support 332 may be combined with one side (e.g., a lower side) of the blocking bar 320.

In an embodiment, the lift structure 330 may be connected to the blocking bar 320. One end 332_S of the lift structure 330 may be combined with the blocking bar 320. Here, the integral connection structure of the lift structure 330 and the blocking bar 320 may be in various forms. For example, the one end 332_S of the lift structure 330 may be connected to one side of the blocking bar 320. This connection structure may be simple to manufacture and easy to maintain. For another example, the one end 332_S of the lift structure 330 may be inserted into the blocking bar 320. This connection structure may provide stronger structural support and alignment stability.

In an embodiment, the lift structure 330 may include the actuator 334. The actuator 334 may drive one end of the lift structure 330 to be lifted or lowered from one surface of the plasma plate 310 in a first direction (e.g., the Z direction).

Referring to FIGS. 10 to 12, the actuator 334 may include a screw actuator. For example, the screw actuator may include a screw 334_S and a screw thread 334_N. Here, the screw 334_S and the screw thread 334_N may correspond to each other to enable precise lifting and lowering of the blocking bar 320. However, the structure of the actuator 334 is not limited thereto, and may be modified into various forms to precisely control the gap between the plasma plate 310 and the blocking bar 320. For example, the actuator 334 may include an electromechanical actuator. This structure may be formed by combining a motor and a linear guide mechanism, and may ensure high precision and repeatability. For another example, the actuator 334 may include a pneumatic actuator. The pneumatic actuator may provide a simple structure and high durability for lifting and lowering the blocking bar 320 using compressed air. In addition, the actuator 334 having such a structure may have minimal electrical influence on a plasma environment. For another example, the actuator 334 may include a hydraulic actuator. It may be possible for the actuator 334 having such a structure to easily fine-tune the blocking bar 320.

In an embodiment, the driving source 336 may precisely control the position of the lift structure 330 by driving the screw actuator 334. For example, the driving source 336 may include a motor to adjust the position of the lift structure 330 in real time during processing of a wafer.

In an embodiment, components of the lift structure 330 may be inserted into the plasma plate 310. For example, the support 332 may be combined with the blocking bar 320 through a through hole PH formed in the plasma plate 310. In addition, at least a portion of the support 332, the actuator 334, and the driving source 336 may be inserted into the plasma plate 310. Here, the height HP of the plasma plate 310 in the first direction (e.g., the Z direction) may be sufficiently high to accommodate at least some of the components of the lift structure 330. Further, the height HP of the plasma plate 310 may be configured not to affect a path and a radiation angle of an ion beam passing through the first opening G1 formed on the plasma plate 310.

As the lift structure 330 is combined with the blocking bar 320, the mounting tolerance may be eliminated, thereby minimizing the error in the position of the blocking bar 320. In addition, stability may be secured against vibration or positional changes that may occur during processing of the wafer of the ion beam processing system. Further, the blocking bar 320 may symmetrically cover the first opening G1, the symmetry and the accuracy of an incident angle of an ion beam passing through the first opening G1 may be guaranteed.

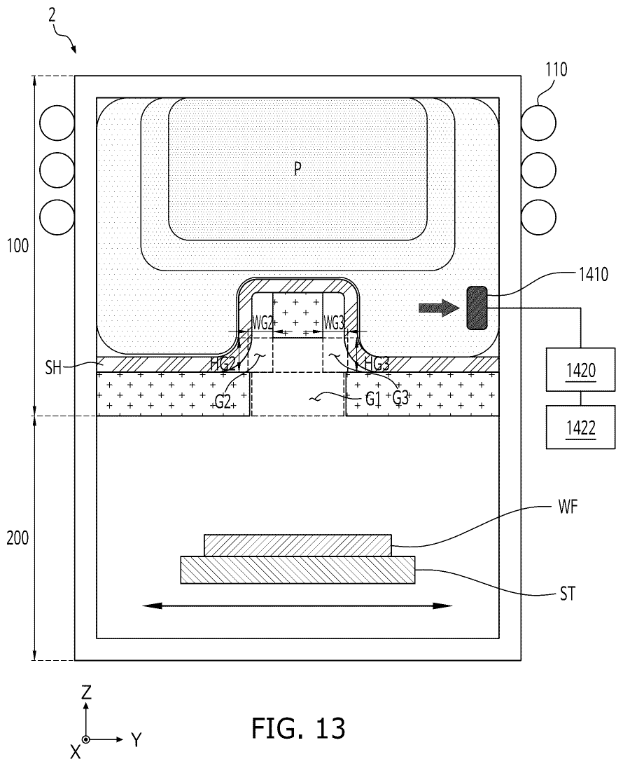

FIG. 13 is a cross-sectional view for illustrating an ion beam processing system according to an embodiment of the present disclosure.

An ion beam processing system 2 may include the plasma chamber 100, the process chamber 200, a slit structure, and a plasma sheath sensor. The sheath sensor may be configured to detect a plasma sheath region SH within the plasma chamber 100 and transmit a control signal to a lift structure. Here, the sheath sensor may include a probe 1410, a detector 1420, and a controller 1422. Hereinafter, parts of the description of FIG. 13 overlapping with the descriptions of FIGS. 1 to 12 may be summarized or not repeated.

In an embodiment, the sheath sensor may include the probe 1410. The probe 1410 may be configured to directly measure electrical properties of the sheath region SH within the plasma chamber 100. The probe 1410 may float in the plasma chamber 100. The probe 1410 may include an electrical probe configured to determine potential distribution of plasma P within the plasma chamber 100. However, the structure of the probe 1410 is not limited thereto, and may be modified into various forms to be suitable for detecting the sheath region SH. For example, the probe 1410 may include an optical probe configured to determine at least one of density and optical properties of the plasma P within the plasma chamber 100. The optical probe may include a laser induced fluorescence (LIF) system that detects a fluorescence signal emitted by radiating a laser of a specific wavelength into the plasma, an optical emission spectrometer (OES) that analyzes a plasma emission spectrum, etc.

In an embodiment, the sheath sensor may include the detector 1420. The detector 1420 may be configured to determine the state of the plasma within the plasma chamber 100 based on data transmitted from the probe 1410.

In an embodiment, the sheath sensor may include the controller 1422. The controller 1422 may be configured to generate a control signal based on data analyzed by the detector 1420 and transmit it to a lift structure (e.g., the lift structure 330).

The sheath sensor may allow the ion beam processing system 2 to monitor the state of plasma in real time and transmit a control signal to the lift structure to adjust the position of the blocking bar 320, so that an ion beam having radiation properties for processing of a wafer may be extracted from the plasma. The lift structure may move the blocking bar (e.g., the blocking bar 320) to place it within the sheath region SH detected by the sheath sensor based on the control signal provided by the sheath sensor. In addition, the lift structure may move the blocking bar to position the second opening G2 and the third opening G3 between the blocking bar and the plasma plate within the sheath region SH.

As a result, the sheath sensor and the lift structure may exchange control signals in real time, so that the ion beam processing system 2 may quickly respond to changes in a plasma environment, and the distortion of path of an ion beam or the unevenness of radiation thereof that may occur during processing of a wafer may be minimized.

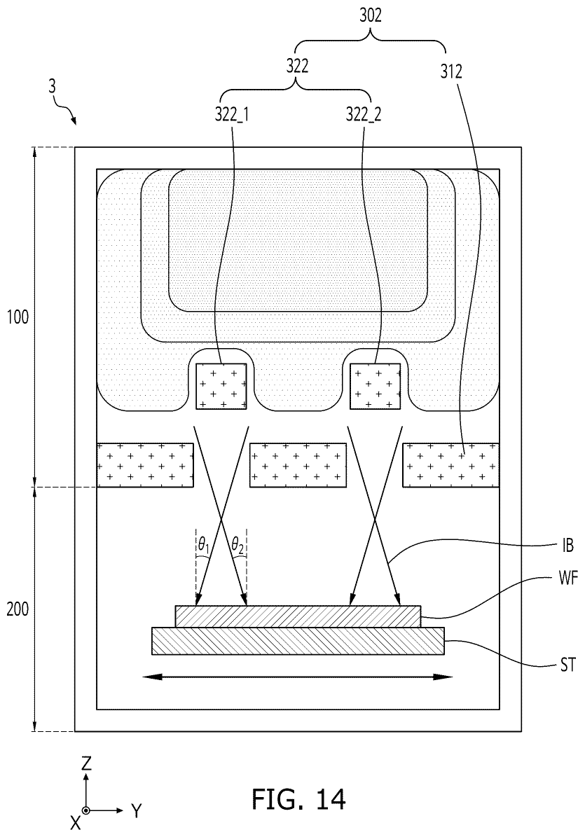

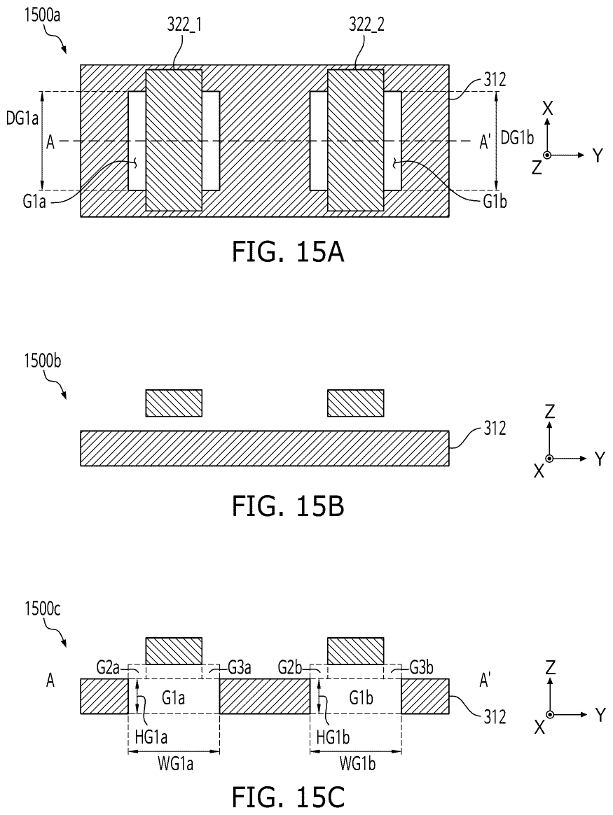

FIG. 14 is a cross-sectional view for illustrating an ion beam processing system according to an embodiment of the present disclosure. FIGS. 15A-C is a top view 1500a, side view 1500b, and A-A′ cross-sectional view 1500c for illustrating a slit structure in FIG. 14, respectively.

Referring to FIGS. 14 and 15A-C, an ion beam processing system 3 may include the plasma chamber 100, the process chamber 200, and a slit structure 302. Within the process chamber 200, a wafer WF to be processed using an ion beam IB extracted from plasma and a stage ST supporting the wafer WF may be placed. The slit structure 302 may include a plasma plate 312 and a plurality of blocking bars 322. Hereinafter, parts of the descriptions of FIGS. 14 and 15 overlapping with the descriptions of FIGS. 1 to 13 may be summarized or not repeated.

In an embodiment, the plasma plate 312 may include a plurality of openings. For example, the plurality of openings may include a first-first opening G1a and a first-second opening G1b. Referring to FIG. 15, the first-first opening G1a and the first-second opening G1b may be formed in the plasma plate 312 in the shape of a slit extending a first direction (e.g., the Z direction), through the plasma plate 312 in a second direction (e.g., the X direction) intersecting the first direction (e.g., the Z direction). The first-second opening G1b may be spaced apart from the first-first opening G1a by a predetermined distance in a third direction (e.g., the Y direction) intersecting the first direction (e.g., the Z direction) and the second direction (e.g., the X direction).

In an embodiment, the first-first opening G1a may have a height HG1a in a first direction (e.g., the Z direction), a depth DG1a in a second direction (e.g., the X direction) intersecting the first direction (e.g., the Z direction), and a width WG1a in a third direction (e.g., the Y direction) intersecting the first direction (e.g., the Z direction) and the second direction (e.g., the X direction). In addition, the first-second opening G1b may have a height HG1b in the first direction (e.g., the Z direction), a depth DG1b in the second direction (e.g., the X direction), and a width WG1b in the third direction (e.g., the Y direction).

In an embodiment, the plurality of blocking bars 322 may include a first blocking bar 322_1 and a second blocking bar 322_2. The first blocking bar 322_1 may be arranged to face the first opening G1a in a first direction (e.g., the Z direction). In addition, the second blocking bar 322_2 may be arranged to face the second opening G1b in the first direction (e.g., the Z direction).

In an embodiment, a second-first opening G2a and a third-first opening G3a may be formed between the first blocking bar 322_1 and the plasma plate 312. In addition, a second-second opening G2b and a third-second opening G3b may be formed between the second blocking bar 322_2 and the plasma plate 312.

In an embodiment, the ion beam IB extracted from the plasma may pass through the first-first opening G1a through the second-first opening G2a and the third-first opening G3a to be radiated onto the wafer WF in the process chamber 200. An incident angle θ₂ at which the ion beam IB passing through the first-first opening G1a through the second-first opening G2a is radiated onto the wafer WF may be substantially identical to an incident angle θ₁ at which the ion beam IB passing through the first-second opening G1b through the second-second opening G2b is radiated onto the wafer WF. In addition, the ion beam IB may pass through the first-second opening G1b through the second-second opening G2b and the third-second opening G3b to be radiated onto the wafer WF in the process chamber 200.

As such, an array of the plurality of openings and blocking bars may be provided in the slit structure, thereby allowing the ion beam processing system to symmetrically form a plurality of ion beams IBs simultaneously. This may improve the efficiency of processing of the wafer.

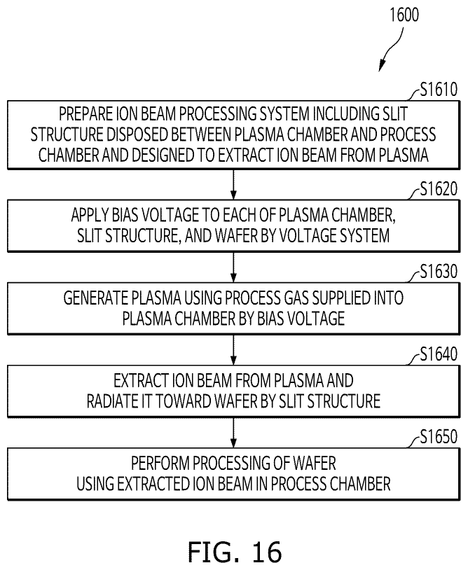

FIG. 16 is a flowchart for illustrating an ion beam processing method according to an embodiment of the present disclosure.

Referring to FIG. 16, the ion beam processing method 1600 may begin with an operation S1610 of preparing an ion beam processing system including a slit structure disposed between a plasma chamber and a process chamber and configured to extract an ion beam from plasma. The slit structure may include a plasma plate, a blocking bar, and a lift structure. The plasma plate may be disposed on one side of the plasma chamber, and an opening of the plasma chamber through which an ion beam passes may be formed on the plasma plate. The blocking bar may be positioned within the plasma chamber with a gap with the opening. The lift structure may be connected to the blocking bar and may be configured to control an angle at which an ion beam passing through the opening is radiated by adjusting the gap between the plasma plate and the blocking bar in a first direction. Here, the lift structure may be combined with the blocking bar.

Next, in operation S1620, a bias voltage may be applied to each of the plasma chamber, the slit structure, and a wafer by a voltage system. Here, the bias voltages applied to each of the plasma chamber, the slit structure, and the wafer may be different from each other.

In operation S1630, plasma may be generated using process gas supplied into the plasma chamber by the bias voltage. For example, plasma may be generated from the process gas supplied into the plasma chamber by the bias voltage applied to the plasma chamber.

In addition, in operation S1640, an ion beam may be extracted from the plasma and radiated toward the wafer by the slit structure. In this step, a sheath sensor may detect a sheath region of the plasma within the plasma chamber in real time and transmit a control signal to the lift structure. In addition, the lift structure may move the blocking bar to place it within the detected sheath region based on the control signal. The extracted ion beam may be radiated toward the wafer positioned within the process chamber.

Next, in operation S1650, the wafer may be processed using the ion beam in the process chamber 200.

Although non-limiting example embodiments of the present disclosure have been described with reference to the accompanying drawings, embodiments of the present disclosure are not limited thereto. By a person having ordinary skill in the technical field to which the present disclosure belongs, various modifications and variations can be made to embodiments of the present disclosure. Such modifications and variations are included within the spirit and scope of the present disclosure.

What is claimed is:

1. An ion beam source apparatus, comprising:
a plasma chamber configured to generate plasma; and
a slit structure configured to extract an ion beam from the plasma and radiate the ion beam toward a wafer,
wherein the slit structure comprises:
a plasma plate on a side of the plasma chamber, the plasma plate including at least one opening through which the ion beam passes;
at least one blocking bar within the plasma chamber, the at least one blocking bar spaced apart from the at least one opening by a gap, the gap being between the plasma plate and the at least one blocking bar in a first direction; and
a lift structure connected to the at least one blocking bar, the lift structure configured to control an angle at which the ion beam passing through the at least one opening is radiated by adjusting the gap between the plasma plate and the at least one blocking bar in the first direction.

2. The ion beam source apparatus as claimed in claim 1, wherein the at least one opening penetrates the plasma plate, and has a shape of a slit extending in a second direction intersecting the first direction.

3. The ion beam source apparatus as claimed in claim 1, wherein the lift structure is connected to the at least one blocking bar.

4. The ion beam source apparatus as claimed in claim 3, wherein the lift structure comprises an actuator that is configured to drive one end of the lift structure to be lifted or lowered from a surface of the plasma plate in the first direction, and
wherein the one end of the lift structure is connected to the at least one blocking bar.

5. The ion beam source apparatus as claimed in claim 4, wherein the actuator comprises at least one from among an electromechanical actuator and a pneumatic actuator.

6. The ion beam source apparatus as claimed in claim 4, wherein the actuator comprises a screw actuator that is configured to be driven by an electric motor.

7. The ion beam source apparatus as claimed in claim 1, further comprising a sheath sensor that is configured to detect a sheath region of the plasma within the plasma chamber in real time and transmit a control signal to the lift structure,
wherein the lift structure is configured to position, based on the control signal, the at least one blocking bar within the sheath region, which is detected, by moving the at least one blocking bar.

8. The ion beam source apparatus as claimed in claim 7, wherein the sheath sensor comprises an electrical probe that is in the plasma chamber, the sheath sensor configured to determine a potential distribution of the plasma within the plasma chamber.

9. The ion beam source apparatus as claimed in claim 7, wherein the sheath sensor comprises an optical probe that is configured to determine at least one from among a density and an optical property of the plasma within the plasma chamber.

10. The ion beam source apparatus as claimed in claim 1, further comprising a blocking bar guide configured to align the at least one blocking bar to be horizontal to the plasma plate.

11. The ion beam source apparatus as claimed in claim 10, wherein the blocking bar guide is spaced apart from the at least one opening by a predetermined distance on a side of the plasma plate within the plasma chamber.

12. The ion beam source apparatus as claimed in claim 10, wherein the blocking bar guide comprises a concave shape that is recessed in a surface of the plasma plate, and
wherein the concave shape corresponds to a shape of an end of the at least one blocking bar.

13. The ion beam source apparatus as claimed in claim 1, wherein
the at least one opening comprises a first opening and a second opening in the plasma plate, the second opening spaced apart from the first opening in a second direction intersecting the first direction, and
the at least one blocking bar comprises:
a first blocking bar facing the first opening in the first direction; and
a second blocking bar facing the second opening in the first direction.

14. An ion beam processing system, comprising:
a plasma chamber configured to generate plasma;
a process chamber connected to the plasma chamber, wherein the process chamber defines a space where processing of a wafer is performed using an ion beam extracted from the plasma;
a slit structure between the plasma chamber and the process chamber, the slit structure configured to extract the ion beam from the plasma and radiate the ion beam toward the wafer; and
a voltage system configured to be electrically connected to each of the plasma chamber, the slit structure, and the wafer to generate an electric field between the plasma chamber and the slit structure and between the slit structure and the wafer,
wherein the slit structure comprises:
a plasma plate connected to the plasma chamber and including at least one opening through which the ion beam passes;
at least one blocking bar within the plasma chamber, the at least one blocking bar spaced apart from the at least one opening by a gap, the gap being between the plasma plate and the at least one blocking bar in a first direction; and
a lift structure connected to the at least one blocking bar, the lift structure configured to control an angle at which the ion beam passing through the at least one opening is radiated by adjusting the gap between the plasma plate and the at least one blocking bar in the first direction.

15. The ion beam processing system as claimed in claim 14, wherein the lift structure is connected to the at least one blocking bar.

16. The ion beam processing system as claimed in claim 14, further comprising a sheath sensor configured to detect a sheath region of the plasma within the plasma chamber in real time and transmit a control signal to the lift structure,
wherein the lift structure is configured to position, based on the control signal, the at least one blocking bar within the sheath region, which is detected, by moving the at least one blocking bar.

17. The ion beam processing system as claimed in claim 14, further comprising a blocking bar guide configured to align the at least one blocking bar to be horizontal to the plasma plate.

18. The ion beam processing system as claimed in claim 14, wherein
the at least one opening comprises a first opening and a second opening in the plasma plate, the second opening spaced apart from the first opening in a second direction intersecting the first direction, and
the at least one blocking bar comprises:
a first blocking bar facing the first opening in the first direction; and
a second blocking bar facing the second opening in the first direction.

19. An ion beam processing method, comprising:
applying, by a voltage system of an ion beam processing system, a bias voltage to each of a plasma chamber of the ion beam processing system, a slit structure of the ion beam processing system, and a wafer, wherein the slit structure is between the plasma chamber and a process chamber of the ion beam processing system;
generating, by the bias voltage, plasma using a process gas supplied into the plasma chamber;
extracting, by the slit structure, an ion beam from the plasma and radiating the ion beam toward the wafer; and
performing, in the process chamber, processing of the wafer using the ion beam,
wherein the slit structure includes:
a plasma plate on a side of the plasma chamber, the plasma plate including an opening through which the ion beam passes;
a blocking bar within the plasma chamber, the blocking bar spaced apart from the opening by a gap, the gap being between the plasma plate and the blocking bar in a first direction; and
a lift structure connected to the blocking bar, the lift structure configured to control an angle at which the ion beam passing through the opening is radiated by adjusting the gap between the plasma plate and the blocking bar in the first direction.

20. The ion beam processing method as claimed in claim 19, wherein the lift structure is connected to the blocking bar.
